(19) United States
(12) Patent Application Publication
(10) Pub. No.: US 2007/0166913 A1
(43) Pub. Date: Jul. 19, 2007

(54) Semiconductor device and method of forming the same

(75) Inventors: Seok-Jun Won, Seoul (KR); Ju-Youn Kim, Suwon-si (KR); Weon-Hong Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/606,891

(22) Filed: Dec. 1, 2006

(30) Foreign Application Priority Data
Jan. 19, 2006 (KR) 10-2006-0005959

(51) Int. Cl. H01L 21/8244

(52) U.S. Cl. 438/238

(57) ABSTRACT

There is provided a method of forming a semiconductor device. A dielectric layer including a metal (e.g., a gate insulating layer and/or a tunnel insulating layer) may be formed on a substrate, and a metal nitride layer containing more metal component than nitrogen may be formed on the dielectric layer by PEALD. The metal nitride layer may be formed by alternately supplying a metal source including the metal and an NH₃ gas, and providing plasma during a supplying of the NH₃ gas. Because a material included in the dielectric layer and that included in the electrode formed thereon react with each other by a high temperature process, characteristics of the semiconductor device may be reduced or prevented from being degraded.

### PRIORITY STATEMENT

This application claims priority under 35 USC §119 to Korean Patent Application No. 10-2006-0003493, filed on Jan. 19, 2006, in the Korean Intellectual Property Office (KIPO), the entire contents of which are incorporated herein by reference.

### BACKGROUND

1. Field

Example embodiments relate to a semiconductor device and a method of forming the same. Other example embodiments relate to a semiconductor device having an electrode on a dielectric layer and a method of forming the same.

2. Description of the Related Art

As semiconductor devices become more highly integrated, a high-k dielectric material (e.g., HfO₂, ZrO₂ and/or Ta₂O₅) may be used for a dielectric layer. The high dielectric material for a capacitor and a gate dielectric layer may require the use of a metal nitride (e.g., TiN and/or TaN) for an electrode. In a metal-insulator-metal (MIM) structure and/or a metal-insulator-silicon (MIS) structure, which is a structure where a high-k dielectric layer and a metal nitride electrode are stacked, electrical characteristics may be deteriorated by an interfacial reaction between a high-k dielectric layer and the metal nitride electrode.

For example, in a structure where a TiN layer is formed on an HfO₂ layer, because the oxygen affinity is different between titanium (Ti) and Hafnium (Hf), the titanium may take oxygen away from the HfO₂ layer and may react with the oxygen during a TiN layer forming process and/or following a high temperature process. Accordingly, an upper portion of the HfO₂ layer may change into HfOₓ with undesired Hf and deficient oxygen, which may lead to a leakage current. A TiO₂ layer may be generated within the TiN layer, which may increase resistance of the electrode.

When the TiN layer is formed on the HfO₂ layer by a metal-organic chemical vapor deposition (MOCVD) process using plasma, an increase in plasma power may lead to an increase of HfNₓ component. FIG. I illustrates X-ray photon spectroscopy (XPS) analysis results for an HfO₂ thin layer with a plasma MOCVD-TiN layer formed on its upper surface. In the MOCVD-TiN layer, the plasma power may be increased in order to remove various impurities (e.g., carbon) included in a metal organic material that is a source material and may make the layer dense. An increase in plasma power may generate HfNₓ on an upper portion of the HfO₂ layer and deteriorate electrical characteristics of the HfO₂ dielectric layer. Therefore, due to the aforementioned characteristics of the high-k dielectric materials, forming the electrode on the high-k dielectric layer may require relatively low plasma power and relatively low process temperature.

### SUMMARY

Example embodiments provide a method of forming semiconductor devices reducing or preventing an interfacial reaction between a high-k dielectric layer and a metal electrode formed thereon. Example embodiments provide semiconductor devices reducing or preventing an interfacial reaction between a high-k dielectric layer and a metal electrode formed thereon.

According to example embodiments, a method of forming a semiconductor device may include forming a dielectric layer including a metal oxide on a substrate and forming a metal nitride layer containing more metal component than nitrogen on the dielectric layer by a PEALD (plasma enhanced atomic layer deposition) process. The metal oxide and the metal nitride layer may contain the same metal. The metal nitride layer may be any one selected from the group consisting of hafnium nitride(HfN) layer, zirconium nitride(ZrN) layer, and tantalum nitride(TaN) layer.

In some embodiments, the metal nitride layer may be formed by alternately supplying a metal source containing the metal and a nitrogen containing gas and providing plasma during a supplying of the nitrogen containing gas. The nitrogen containing gas may be NH₃. The metal source may be TetraethylMethyl amino-Hf (TEMA-Hf), and the metal nitride layer may be an hafnium nitride(HfN) layer. In other embodiments, the dielectric layer may be a gate insulating layer or a tunnel insulating layer.

In yet other embodiments, an upper portion of the dielectric layer may be a metal oxinitride layer containing the metal. The metal oxinitride layer may be formed by sequentially supplying a metal source containing the metal, a nitrogen containing gas, and an oxygen containing gas and providing plasma during a supplying of at least one of the nitrogen containing gas and the oxygen containing gas. The nitrogen containing gas may be NH₃.

In further embodiments, the dielectric layer may be formed by alternately supplying a metal source containing the metal and a mixture gas of nitrogen and oxygen and providing plasma during a supplying of the mixture gas. The dielectric layer may be formed by alternately supplying a metal source containing the metal and any one of a nitrous oxide (N₂O) gas and a nitrogen dioxide (NO₂) gas and providing plasma during a supplying of the gas. In yet further embodiments, the method may further include, before forming the dielectric layer, forming a metal nitride layer containing more metal component than nitrogen on the substrate by the PEALD process.

According to other example embodiments, a semiconductor device may include a semiconductor substrate, a dielectric layer on the semiconductor substrate and including a metal oxide and a metal nitride layer formed on the dielectric layer by the PEALD process and containing more metal component than nitrogen. The metal oxide and the metal nitride layer may contain the same metal.

In some embodiments, the metal nitride layer may be any one selected from the group consisting of hafnium nitride(HfNₓ) layer, zirconium nitride(ZrNₓ) layer, and tantalum nitride(TaNₓ) layer. In other embodiments, the dielectric layer may be a gate insulating layer or a tunnel insulating layer. In yet other embodiments, an upper portion of the dielectric layer may be an oxinitride layer of the metal. In further embodiments, the semiconductor device may further include a metal nitride layer between the semiconductor substrate and the dielectric layer and containing more metal component than nitrogen.

According to example embodiments, a method of forming a semiconductor device may include forming a dielectric layer including a metal oxide and forming a metal nitride layer containing more metal component than nitrogen, wherein the metal oxide and the metal nitride layer contain a same metal. Forming the metal nitride layer may include forming the metal nitride layer by plasma enhanced atomic layer deposition. The dielectric layer may be formed on a substrate and the metal nitride layer may be formed on the dielectric layer.

According to example embodiments, a semiconductor device may include a semiconductor substrate, a dielectric layer including a metal oxide on the semiconductor substrate and a metal nitride layer containing more metal component than nitrogen on the semiconductor substrate, wherein the metal oxide and the metal nitride layer contain a same metal. The metal nitride layer may be formed by plasma enhanced atomic layer deposition. The metal nitride layer may be on the dielectric layer.

### BRIEF DESCRIPTION OF THE DRAWINGS

Example embodiments will be more clearly understood from the following detailed description taken in conjunction with the accompanying drawings. FIGS. 1-5B represent non-limiting, example embodiments as described herein.

FIG. 1 illustrates an X-ray photon spectroscopy analysis result about a conventional HfO₂ thin layer with a plasma MOCVD-TiN formed on its upper surface;

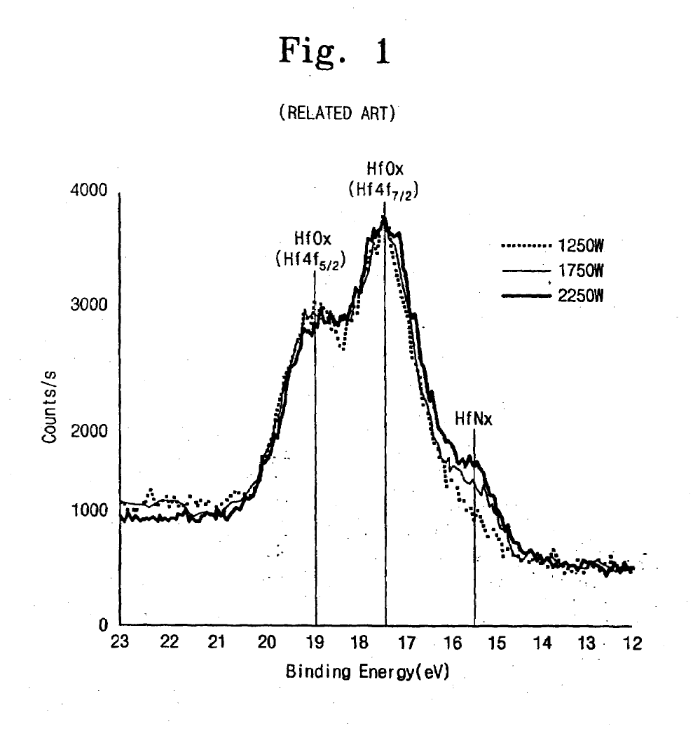

FIGS. 2A and 2B are diagrams of a stack structure according to example embodiments;

FIG. 3 is a diagram illustrating a plasma enhanced atomic layer deposition (PEALD) process according to example embodiments;

FIG. 4 is a diagram illustrating an auger electron spectroscopy analysis result about an HfN layer formed on a silicon substrate by a PEALD process; and

FIGS. 5A and 5B are diagrams of a stack structure according to example embodiments.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof. It will be understood that the terms “a metal nitride layer containing more metal component than nitrogen” means an atomic ratio in a chemical formula.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

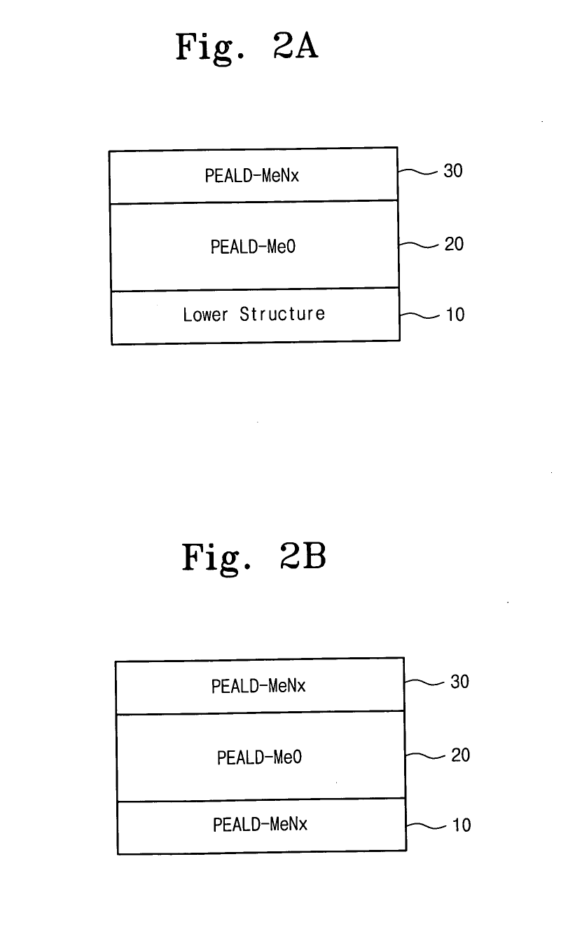

FIGS. 2A and 2B are diagrams of a stack structure according to example embodiments. Referring to FIGS. 2A and 2B, a dielectric layer 20 including a metal oxide (MeO) may be formed on a lower structure 10 and a metal nitride (MeNx) layer 30 may be formed on the dielectric layer 20. The metal oxide and the metal nitride may contain the same material. The lower structure 10 may be a semiconductor substrate, a lower electrode of a dynamic random access memory (DRAM) capacitor, a floating gate electrode of a nonvolatile memory device and/or a charge storage layer of a nonvolatile memory device having a silicon-oxide-nitride-oxide-silicon (SONOS) structure. Accordingly, the dielectric layer 20 may be a gate insulating layer, a tunnel insulating layer, a dielectric layer for a capacitor, an interlayer dielectric layer between a floating gate electrode and a control gate of a nonvolatile memory device and/or a blocking insulating layer on a charge storage layer in the SONOS structure.

The metal nitride (MeNx) layer 30 may include more metal content than nitrogen in order to have a high conductivity and may be formed by a plasma enhanced atomic layer deposition (PEALD) process. A general atomic layer deposition (ALD) process, which uses heat to discompose an ALD source, may have relative difficulty in forming a metal nitride layer with high quality. Therefore, in order to form the metal nitride layer with high quality as an electrode on the dielectric layer, plasma may be used to decompose the ALD source. The metal (Me) may be hafnium (Hf), zirconium (Zr) and/or tantalum (Ta). Accordingly, the dielectric layer may be a hafnium oxide(HfO₂) layer, zirconium oxide(ZrO₂) layer and/or tantalum oxide(Ta₂O₅) layer and the metal nitride layer may be an hafnium nitride(HfNₓ) layer, zirconium nitride(ZrNₓ) layer and/or tantalum nitride(TaNₓ) layer. Herein, 0<x<1. When the same metal is included in both the dielectric layer and the electrode formed thereon, interdiffusion between a metal element in the dielectric layer and that in the electrode may be reduced or prevented. When the dielectric layer is used as a gate insulating layer subjected to a high temperature heat treatment, the reduction or prevention of interdiffusion may become more important.

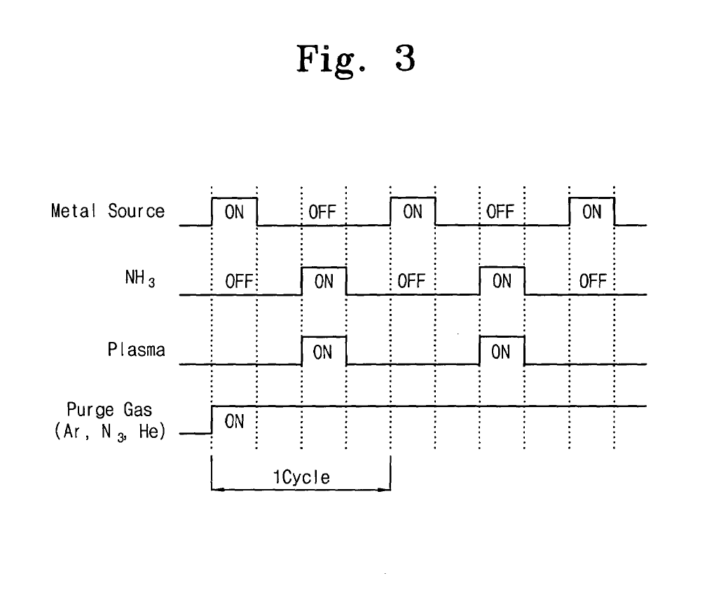

FIG. 3 is a diagram illustrating a PEALD process according to example embodiments. Referring to FIG. 3, the metal nitride layer may be formed by alternately supplying a metal source including the metal and a NH₃ gas. Plasma may be provided by supplying the NH₃ gas. For stable deposition, the plasma may be turned on simultaneously with supplying the NH₃ gas or about 0.5 seconds after supplying the NH₃ gas. The metal source and the NH₃ gas may be supplied for about 1 second to about 2 seconds. A purge gas may be supplied between supplying the metal source and the NH₃ gas. The purge gas may be continuously supplied during the PEALD process. The purge gas may be Ar gas, N₂ gas and/or He gas. A sequential supply of gases may form a cycle of the PEALD process. Process pressure may range from about 1 Torr to about 5 Torr, for example, about 3 Torr. Plasma power of about 1000 W or less, for example, about 600 W, may be used so as to reduce or prevent the nitration of metal component of the dielectric layer. Various metal sources may be used for the PEALD process. For example, when the metal is Hf, TetraethylMethyl Amino-Hf (TEMA-Hf) may be used. The process temperature may range from about 200° C. to about 400° C., for example, about 300° C. Because the metal nitride layer is formed at a lower temperature using the relatively low plasma power, the dielectric layer thereunder may reduce or prevent nitration.

The dielectric layer may be formed by alternately supplying a metal source including the metal and a mixture gas of nitrogen and oxygen. Plasma may be provided during the supply of the mixture gas. For example, the metal may be Hf and the dielectric layer may be an hafnium oxide(HfO₂) layer. When the hafnium oxide(HfO₂) layer is formed using the mixture gas of nitrogen and oxygen, the deposition rate may increase about 1.25 times in comparison with using only oxygen. Although nitrogen may not be included in hafnium oxide(HfO₂) dielectric layer, the deposition rate may increase.

A gas including both nitrogen and oxygen (e.g., a nitrous oxide (N₂O) gas and/or a nitrogen dioxide (NO₂) gas) may be used as a gas for providing oxide. The N₂O gas may have improved reactivity similar to H₂O and also may include no hydrogen atoms. If the hydrogen is included in a dielectric layer, reliability may decrease. As described above, the dielectric layer may be formed by alternately supplying a metal source including the metal and any one of the N₂O gas and the NO₂ gas. Plasma may be provided while supplying of the gas. The PEALD process using the N₂O gas may increase the deposition rate about 1.7 times in comparison with using oxygen.

The dielectric layer 20 and the metal nitride layer 30 may be formed in the same process chamber by a sequential process, which may be accomplished by altering a kind of source and gas. In the MIM structure as shown in FIG. 2B, the lower structure 10 may also be formed by the PEALD process. Accordingly, the lower structure 10, the dielectric layer 20, and the metal nitride layer 30 may be formed in the same chamber by a sequential process, performing a fabrication process more efficiently.

The process chamber used for the PEALD process according to example embodiments may have a relatively small volume. Therefore, plasma may be turned on/off relatively fast in performing the PEALD process. When the process chamber has a relatively small volume, variable process atmospheres may become stable and the plasma may be more easily maintained and turned on/off. Accordingly, the process chamber may be prepared such that a susceptor, in which wafers are disposed and a lower electrode is provided, may be spaced from an upper electrode for generating plasma by about 3.5 mm. A gas line may be disposed such that the process gas and the source are flowed in through a lateral side of the process chamber.

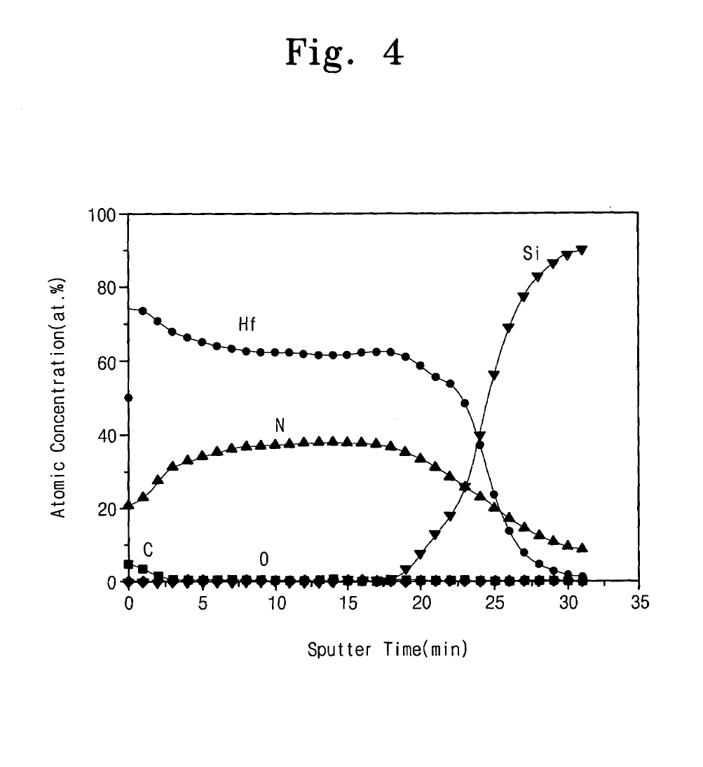

FIG. 4 is a diagram illustrating an AES analysis about the hafnium nitride(HfNₓ) layer formed on a silicon substrate by the PEALD process. The process temperature may be about 300° C. and the plasma power may be about 250 W. The HfNₓ layer may include a relatively small amount of carbon, for example, about 5% to about 10%. The HfNₓ layer may include twice as much metal as the nitrogen, which may become a conducting layer. As described above, it may be relatively difficult to form an HfNₓ thin layer by a general ALD process, but an improved HfNₓ thin layer may be formed by the PEALD process according to example embodiments.

Forming the metal nitride layer by the general PEALD process, in particular in a lateral flowing method, tends to depend on a kind and a state of the lower layer. A supply direction of a gas may affect characteristics of the metal nitride layer. When the gate insulating layer, which the metal nitride layer is formed thereon, may be subjected to the high temperature heat treatment, interdiffusion between oxygen in the gate insulating layer and nitrogen in the metal electrode as well as diffusion of the metal may occur, deteriorating the interfacial characteristics.

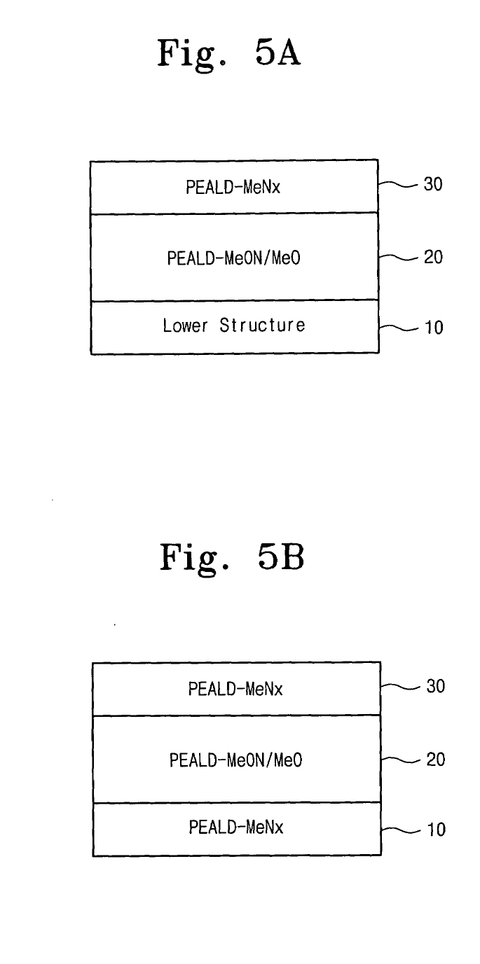

Therefore, when the metal nitride layer is deposited on the dielectric layer, an upper portion of the dielectric layer may be an oxinitride layer of the metal. The metal oxinitride layer may reduce or prevent the diffusion. FIGS. 5A and 5B are diagrams of a stack structure according to example embodiments. The metal oxinitride layer may be formed during deposition of the dielectric layer by the PEALD process. In this process, a metal source including the metal, an NH₃ gas, and an oxygen containing gas may be sequentially supplied, and plasma may be provided during the supply of at least one of the NH₃ gas and the oxygen containing gas. An amount of oxygen and nitrogen included in the metal oxinitride layer may be controlled. For example, in order to increase an amount of nitrogen, the plasma may be provided during the supply of the NH₃ gas, while the plasma is not provided during the supply of oxygen. When a certain kind of metal is used, the oxidation rate may be lower with only the oxygen gas, and thus a relatively small amount of oxygen may be included in the formed layer. Therefore, the plasma may be provided supplying the insufficient oxygen. In order to decrease an amount of nitrogen, the plasma may not be provided during the supply of the NH₃ gas.

The dielectric layer and the metal oxinitride layer included in the dielectric layer may be sequentially formed in the same process chamber by altering a kind of the gas to be supplied. For example, a dielectric layer that is a metal oxide (MeO) layer may be formed on a lower structure 10 (e.g., a substrate) by the PEALD process for supplying a metal source and an oxygen gas. A metal oxinitride (MeON) layer may be formed by the PEALD process for supplying a metal source, an NH₃ gas, and an oxygen containing gas to form a dielectric layer 20 of a MeON/MeO structure. A metal nitride (MeNx) layer 30 may be formed by the PEALD process for supplying a metal source and an NH₃ gas to form the structure shown in FIG. 5A.

In the case of a stack structure shown in FIG. 5B, a metal nitride layer including the metal may be formed on the substrate before forming the dielectric layer, forming a MIM capacitor. The metal nitride (MeNx) layer may include more metal content than nitrogen, and be formed by the PEALD process for supplying a metal source and an NH₃ gas. The metal nitride (MeNx) layer may react with the metal oxide (MeO) layer by subsequent heat treatments, and thus the dielectric layer 20 may become a stack layer of MeON/MeO/MeON.

According to example embodiments, because the interfacial reaction is reduced between the high-k dielectric layer including the metal oxide layer and the metal nitride electrode, electrical characteristics of a capacitor, a metal-oxide-semiconductor (MOS) transistor and/or a flash memory device may be improved. Because the metal oxinitride layer is formed on the high-k dielectric layer before forming the metal nitride layer by the PEALD process, an improved metal nitride layer may be formed. In addition, by controlling the plasma power, the metal nitride layer may be formed on the high-k dielectric layer without damaging the characteristics thereof.

It will be apparent to those skilled in the art that various modifications and variations may be made in example embodiments. Thus, it may be intended that example embodiments cover the modifications and variations provided they come within the scope of the appended claims and their equivalents.

What is claimed is:

1. A method of forming a semiconductor device, comprising:
forming a dielectric layer including a metal oxide on a substrate; and
forming a metal nitride layer containing more metal component than nitrogen on the dielectric layer by plasma enhanced atomic layer deposition,
wherein the metal oxide and the metal nitride layer contain a same metal.

2. The method of claim 1, wherein forming the metal nitride layer includes forming any one selected from the group consisting of hafnium nitride layer, zirconium nitride layer, and tantalum nitride layer.

3. The method of claim 1, wherein forming the metal nitride layer includes alternately supplying a metal source including the metal and an NH₃ gas and providing plasma during a supplying of the NH₃ gas.

4. The method of claim 3, wherein the plasma power is about 1,000 W or less.

5. The method of claim 3, wherein the plasma power is about 0.35 W/cm² or less per a unit area.

6. The method of claim 3, wherein supplying the metal source includes supplying TetraethylMethyl amino-Hf (TEMA-Hf) and forming the metal nitride layer includes forming a hafnium nitride layer.

7. The method of claim 1, wherein forming the dielectric layer includes forming a gate insulating layer or a tunnel insulating layer.

8. The method of claim 1, wherein an upper portion of the dielectric layer is a metal oxinitride layer containing the same metal.

9. The method of claim 8, wherein a source and a gas for the plasma enhanced atomic layer deposition are supplied through a lateral side of the substrate.

10. The method of claim 8, wherein forming the metal oxinitride layer includes sequentially supplying a metal source containing the same metal, an NH₃ gas, and an oxygen containing gas and providing plasma during a supplying of at least one of the NH₃ gas and the oxygen containing gas.

11. The method of claim 1, wherein forming the dielectric layer includes alternately supplying a metal source containing the same metal and a mixture gas of nitrogen and oxygen and providing plasma during a supplying of the mixture gas.

12. The method of claim 1, wherein forming the dielectric layer includes alternately supplying a metal source including the metal and any one of a nitrous oxide (N₂O) gas and a nitrogen dioxide (NO₂) gas and providing plasma during a supplying of the gas.

13. The method of claim 1, before forming the dielectric layer, further comprising:
forming the metal nitride layer containing more metal component than nitrogen on the substrate by the plasma enhanced atomic layer deposition.

14. A semiconductor device, comprising:
a semiconductor substrate;
a dielectric layer on the semiconductor substrate and including a metal oxide; and
a metal nitride layer on the dielectric layer formed by PEALD and containing more metal component than nitrogen,
wherein the metal oxide and the metal nitride layer contain a same metal.

15. The semiconductor device of claim 14, wherein the metal nitride layer is any one selected from the group consisting of hafnium nitride layer, zirconium nitride layer, and tantalum nitride layer.

16. The semiconductor device of claim 14, wherein the dielectric layer is a gate insulating layer or a tunnel insulating layer.

17. The semiconductor device of claim 14, wherein the carbon content of the metal nitride layer is about 10% or less.

18. The semiconductor device of claim 14, wherein an upper portion of the dielectric layer is an oxinitride layer containing the same metal.

19. The semiconductor device of claim 14, further comprising:
a metal nitride layer formed between the semiconductor substrate and the dielectric layer and containing more metal component than nitrogen.

20. The semiconductor device of claim 19, further comprising:
a metal oxinitride layer formed between the metal nitride layer and the dielectric layer.

21. A method of forming a semiconductor device, comprising:
forming a dielectric layer including a metal oxide; and
forming a metal nitride layer containing more metal component than nitrogen, wherein the metal oxide and the metal nitride layer contain a same metal.

22. The method of claim 21, wherein forming the metal nitride layer includes forming the metal nitride layer by plasma enhanced atomic layer deposition.

23. The method of claim 21, wherein the dielectric layer is formed on a substrate and the metal nitride layer is formed on the dielectric layer.

24. A semiconductor device, comprising:
a semiconductor substrate;
a dielectric layer including a metal oxide on the semiconductor substrate; and
a metal nitride layer containing more metal component than nitrogen on the semiconductor substrate, wherein the metal oxide and the metal nitride layer contain a same metal.

25. The semiconductor device of claim 24, wherein the metal nitride layer is formed by plasma enhanced atomic layer deposition.

26. The semiconductor device of claim 24, wherein the metal nitride layer is on the dielectric layer.
